(19) United States
(12) Patent Application Publication
(10) Pub. No.: US 2025/0014876 A1
(43) Pub. Date: Jan. 9, 2025

(54) USING PLASMA ENHANCED PROCESS TO DO PERIODIC MAINTENANCE

(71) Applicant: SKY TECH INC., Hsinchu County (TW)

(72) Inventors: JUNG-HUA CHANG, Hsinchu County (TW); CHING-LIANG YI, Hsinchu County (TW); YU-CHI LIU, Hsinchu County (TW)

(21) Appl. No.: 18/219,022

(22) Filed: Jul. 6, 2023

(51) Int. Cl. H01J 37/32; H01L 21/02

(52) U.S. Cl. CPC H01J 37/3288; H01L 21/0228; H01J 2237/332; H01L 21/68757

(57) ABSTRACT

This disclosure is a method of using plasma enhanced process to do periodic maintenance. The method includes performing a first atomic layer deposition on a substrate on a carrier disk to form a thin film on the substrate, and determining that an insulating film deposited on an edge of a surface of the carrier disk has a thickness greater than a pre-determined value. A second atomic layer deposition is performed on the carrier disk without the substrate placed thereon, to from a conductive film on the insulating film of the carrier disk, so that the carrier disk has conductive properties. Then the substrate is placed on the carrier disk, and the first atomic layer deposition is performed on the substrate on the carrier disk. Through the method, the cycle of cleaning and maintaining the carrier disk is greatly extended to improve the rate of equipment usage.

### BACKGROUND

### Technical Field

This disclosure relates to a method of using plasma enhanced process to do periodic maintenance. The cycle of cleaning and maintaining the carrier disk can be greatly extended, and it is beneficial to improve the rate of equipment usage.

### Related Art

With the continuous development of the integrated circuit technology, current electronic products are developed towards the trend of light, thin, short, high performance, high reliability and intelligence. The miniaturization technology of transistors in electronic products is crucial. As the size of transistors decreases, the current transmission time and power consumption can be reduced, so as to achieve the purpose of fast computation and energy saving. In today's miniaturized transistors, some of the critical films are almost only a few atoms thick, and the atomic layer deposition process is one of the main technologies for developing these micro-structures.

The atomic layer deposition process is a technique for plating substances on the surface of a wafer in the form of single atoms layer by layer. The main reactants of the atomic layer deposition have two chemical substances, commonly referred to as precursors, which are sequentially transferred into the reaction space.

In practical applications, the first precursor is first delivered into the reaction space, so that the first precursor is guided to the surface of the wafer. The inert gas is delivered into the reaction space, and gas us extracted from the reaction space to remove the first precursor remained in the reaction space. The second precursor is injected into the reaction space, so that the second precursor reacts with the first precursor on the surface of the wafer to generate a thin film. Then the inert gas is injected into the reaction space, to remove the second precursor remained in the reaction space. The above steps are repeated to form a thin film on the wafer.

### SUMMARY

This disclosure discloses a novel method of using plasma enhanced process to do periodic maintenance. The method includes steps of performing a first atomic layer deposition on a substrate on a carrier disk to form a thin film on the substrate, and determining whether an insulating film deposited on a surface of the carrier disk has a thickness greater than a pre-determined value.

If the insulating film deposited on the surface of the carrier disk has a thickness greater than the pre-determined value, the substrate on the carrier disk is taken out, and a second atomic layer deposition is performed on the surface of the carrier disk without the substrate placed thereon to form a conductive film on the insulating film of the carrier disk. Then the substrate is placed on the carrier disk, and the first atomic layer deposition is performed on the substrate on the carrier disk. Through the method described in this disclosure, the cycle of cleaning and maintaining the carrier disk can be greatly extended, and it is beneficial to improve the rate of equipment usage.

In order to achieve the above purpose, this disclosure presents a method of using plasma enhanced process to do periodic maintenance. The method includes: performing a first atomic layer deposition on a substrate on a carrier disk to form a thin film on the substrate, wherein when the first atomic layer deposition is performed, an insulating film is formed on the carrier disk; determining that the insulating film of the carrier disk has a thickness greater than a pre-determined value; and performing a second atomic layer deposition on the carrier disk to form a conductive film on the insulating film of the carrier disk.

In at least one embodiment of this disclosure, the method further includes: determining that the number of times the second atomic layer deposition is performed is greater than a threshold; and cleaning the carrier disk to remove the insulating film and the conductive film on the carrier disk.

In at least one embodiment of this disclosure, the method further includes: sequentially delivering a first precursor and a second precursor to a containing space of a chamber; and performing the first atomic layer deposition on the substrate on the carrier disk, wherein the carrier disk is located in the containing space of the chamber.

In at least one embodiment of this disclosure, the method further includes: sequentially delivering a third precursor and the second precursor to the containing space of the chamber; and performing the second atomic layer deposition on the carrier disk in the containing space.

In at least one embodiment of this disclosure, the insulating film has a thickness greater than the conductive film.

In at least one embodiment of this disclosure, the method further includes: taking out the substrate that has completed the first atomic layer deposition from the carrier disk; and then performing the second atomic layer deposition on the carrier disk.

In at least one embodiment of this disclosure, the method further includes after the second atomic layer deposition is completed, placing the substrate on the carrier disk; and performing the first atomic layer deposition.

In at least one embodiment of this disclosure, the pre-determined value is 1000 Å.

In at least one embodiment of this disclosure, the conductive film has a thickness greater than 300 Å.

In at least one embodiment of this disclosure, a precursor used for the first atomic layer deposition is different from a precursor used for the second atomic layer deposition.

### BRIEF DESCRIPTION OF THE DRAWINGS

This disclosure will become more fully understood from the detailed description given herein below for illustration only, and thus not limitative of this disclosure, wherein:

FIG. 1 is a flowchart of a method for using plasma enhanced process to do periodic maintenance according to an embodiment of this disclosure.

FIG. 2 is a schematic cross-sectional view of a deposition apparatus suitable for a method of using plasma enhanced process to do periodic maintenance according to an embodiment of this disclosure.

FIG. 3 is a schematic cross-sectional view of a carrier disk formed by a method for using plasma enhanced process to do periodic maintenance according to an embodiment of this disclosure.

### DETAILED DESCRIPTION

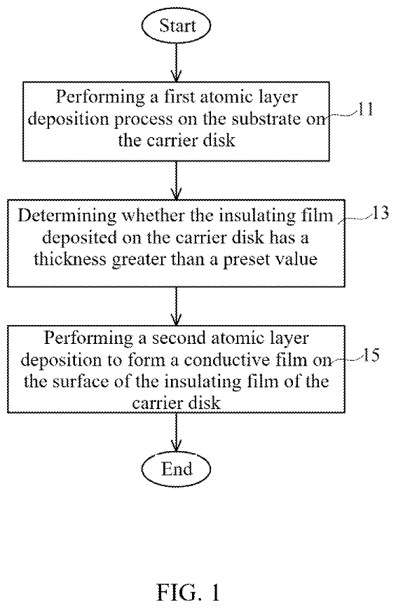

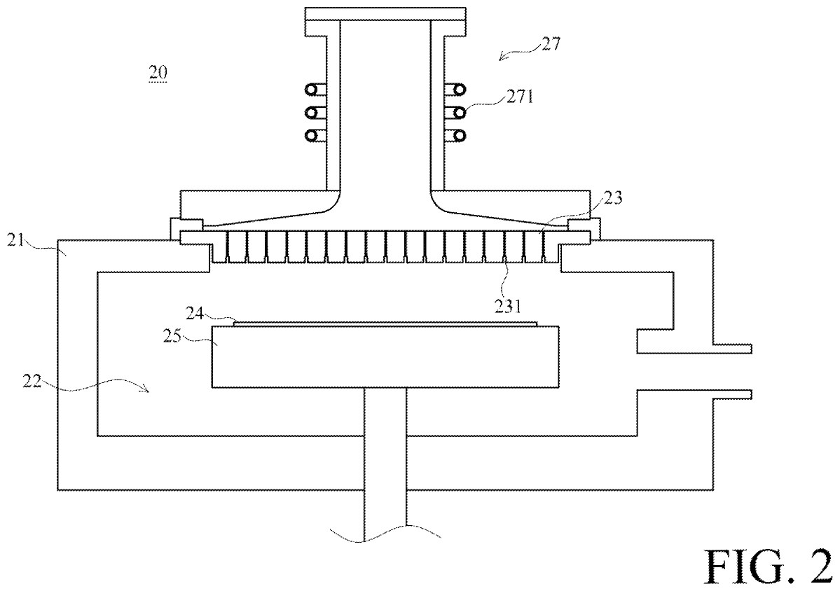

FIG. 1 is a flowchart of a method for using plasma enhanced process to do periodic maintenance according to an embodiment of this disclosure. FIG. 2 is a schematic cross-sectional view of a deposition apparatus suitable for a method of using plasma enhanced process to do periodic maintenance according to an embodiment of this disclosure. The deposition apparatus 20 includes a chamber 21, a shower head 23 and a carrier disk 25. The shower head 23 is connected to the chamber 21 and oriented toward a containing space 22 of the chamber 21, and the carrier disk 25 is located in the containing space 22 of the chamber 21.

The shower head 23 is connected to a delivery pipe line 27. The delivery pipe line 27 is used to deliver one or more precursors to the shower head 23. The shower head 23 includes a plurality of holes 231 through which the precursors are delivered to the containing space 22 of the chamber 21.

In an embodiment of this disclosure, the delivery pipe line 27 further includes an RF coil 271 (Radiofrequency coil 271). In one example, the RF coil 271 is wrapped around the outside of the delivery pipe line 27. The precursors in the delivery pipe line 27 are subjected to the magnetic field generated by the RF coil 271 to form plasma, making the deposition apparatus 20 a plasma-assisted atomic layer deposition apparatus. In addition, the RF coil 271 may be provided around the chamber 21. In various embodiments, the deposition apparatus 20 is not equipped with the RF coil 271 and connects a remote plasma source to the delivery pipe line 27.

The carrier disk 25 is used to carry one or more substrates 24 and is configured to heat the substrates 24 placed in the carrier disk 25. The shower head 23 is located above the carrier disk 25, wherein the holes 231 of the shower head 23 are oriented toward the upper surface of the carrier disk 25 and the substrate 24.

During the deposition process, the precursors are transferred to the shower head 23 via the delivery pipe line 27 and delivered to the carrier disk 25 and the substrate 24 provided on the surface of the carrier disk 25 through the holes 231 of the shower head 23, causing the precursors to contact the carrier disk 25 and the substrate 24 to form a thin film on the surface of the substrate 24.

In practical applications, the first precursor is delivered to the containing space 22 of the chamber 21 through the holes 231 of the shower head 23. The first precursor is deposited on the substrate 24. The inert gas is then injected into the containing space 22 of the chamber 21 through the holes 231 of the shower head 23, to remove the unreacted first precursor and the by-products from the containing space 22.

The second precursor is then delivered into the containing space 22 of the chamber 21 through the holes 231 of the shower head 23. The second precursor reacts with the first precursor on the surface of the substrate 24 to form a thin film. The inert gas is then injected again into the containing space 22 of the chamber 21 through the holes 231 of the shower head 23, to remove the unreacted second precursor and the by-products from the containing space 22.

By repeatedly performing the above cycle, a thin film can be formed on the surface of the substrate 24, and the thickness of the thin film can be controlled by the number of cycles.

In general, the first precursor may be a volatile metal compound, while the second precursor may be a non-metallic compound such as H2O, NH3 or O3. For example, the first precursor is trimethylaluminum (TMA), the second precursor is NH3, and an aluminum nitride (AlN) film is formed on the surface of the substrate 24.

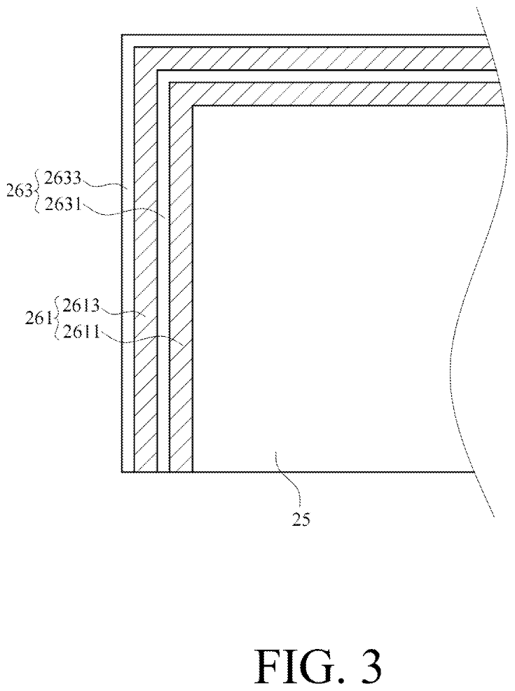

As shown in FIG. 3, during the process of depositing a thin film on the surface of the substrate 24, a thin film is also formed on the surface of the carrier disk 25, which may be a titanium disk, for example, and have conductive properties. After performing the first atomic layer deposition on multiple batches of substrate 24, the thickness of the thin film deposited on the carrier disk 25 will increase and an insulating film 261, such as an aluminum nitride film, will be formed on the surface of the carrier disk 25, causing the carrier disk 25 to gradually lose its conductive properties.

As a result, some important process parameters, such as direct current (DC) bias, cannot be observed when performing plasma-assisted atomic layer deposition (PEALD). In addition, the insulating film 261 on the carrier disk 25 can also cause a decrease in uniformity (U %) of the film deposited on the surface of the substrate 24.

In general, when the insulating film 261 on the surface of the carrier disk 25 is too thick, it is necessary to open the chamber 21 and take out the carrier disk 25 inside the chamber 21 for cleaning, to remove the insulating film 261 deposited on the surface of the carrier disk 25. After completing the cleaning of the carrier disk 25, it can be placed back into the containing space 22 of the chamber 21 and the film deposition can be continued through the deposition apparatus 20.

Through the above steps of cleaning the carrier disk 25, the insulating film 261 deposited on the surface of the carrier disk 25 can be effectively removed, in order to avoid the problems such as the inability to observe part of the process parameters and the decrease of uniformity of the film on the surface of the substrate 24. However, taking out the carrier disk 25 from the chamber 21 and cleaning it will undoubtedly increase the cost and delay the subsequent process. In addition, during the process of opening the chamber 21, it may also cause outside contaminants to enter the containing space 22 of the chamber 21, thereby affecting the subsequent process.

For this reason, this disclosure presents a method of using plasma enhanced process to do periodic maintenance, which can effectively extend the maintenance cycle of the carrier disk 25. As shown in FIG. 1, at least one substrate 24 is placed on the carrier disk 25, a first atomic layer deposition is performed on the substrate 24 on the carrier disk 25, and a thin film is formed on the surface of the substrate 24, as shown in step 11. The first atomic layer deposition is a deposition step generally performed on the surface of the substrate 24. For example, the film formed on the surface of the substrate 24 may be an aluminum nitride.

During the process of performing the first atomic layer deposition on the substrate 24, the precursor also contacts the surface of the carrier disk 25 and forms an insulating film 261 on the carrier disk 25.

It is determined whether the insulating film 261 deposited on the carrier disk 25 has a thickness greater than a pre-determined value, as shown in step 13. In practical applications, the thickness of the insulating film 261 can be deduced from the magnitude of the induced voltage between the RF coil 271 and the carrier disk 25, and it is determined whether the insulating film 261 has a thickness greater than a pre-determined value. The setting of the pre-determined value can be adjusted based on the experience or accumulated data from actually operating the deposition apparatus 20. For example, the pre-determined value can be 1000 Å.

In various embodiments, it is also possible to determine, by the number of cycles in which the first atomic layer is deposited, whether the insulating film 261 deposited on the carrier disk 25 has a thickness greater than a pre-determined value.

When the insulating film 261 on the surface of the carrier disk 25 has a thickness greater than the pre-determined value, a second atomic layer deposition is performed on the carrier disk 25 to form a conductive film 263 on the surface of the insulating film 261 of the carrier disk 25, as shown in step 15.

The insulating film 261 formed by the first atomic layer deposition is a different material from the conductive film 263 formed by the second atomic layer deposition, and the precursors used for the first atomic layer deposition are different from those used for the second atomic layer deposition.

During the process of performing the first atomic layer deposition, the first precursor and the second precursor can be sequentially delivered to the containing space 22 of the chamber 21 via the shower head 23. During the process of performing the second atomic layer deposition, the third precursor and the second precursor is sequentially delivered to the containing space 22 of the chamber 21 via the shower head 23.

In an embodiment of this disclosure, the insulating film 261 is an aluminum nitride, and the conductive film 263 is a titanium nitride. In addition, the first precursor used for the first atomic layer deposition can be trimethylaluminum, while the second precursor is ammonia, and the third precursor used for the second atomic layer deposition is tetra(dimethylamino) titanium (TDMAT) or tetra(diethylamino) titanium (TDEAT), while the second precursor is ammonia.

In practical applications, after the substrate 24 on the carrier disk 25 has completed the first atomic layer deposition, the substrate 24 that has completed the first atomic layer deposition can be taken out from the carrier disk 25. The different precursors are then delivered to the containing space 22 of the chamber 21 through the holes 231 of the shower head 23 and a second atomic layer deposition is performed on the carrier disk 25, to form a conductive film 263 on the surface of the insulating film 261 of the carrier disk 25.

After the second atomic layer deposition is completed, the conductive film 263 deposited on the carrier disk 25 reaches a certain thickness. For example, the conductive film 263 may have a thickness greater than 300 Å, which will enable the carrier disk 25 to have conductive properties. Then the substrate 24 can be placed on the carrier disk 25, and the first atomic layer deposition is continued on the substrate 24.

When the above method is carried out, it is not necessary to open the chamber 21, and also not necessary to take out the carrier disk 25 from the chamber 21, which can significantly reduce the time and cost spent on cleaning the carrier disk 25, and can avoid the contamination that may arise during the process of opening the chamber 21.

In an embodiment of this disclosure, as shown in FIG. 3, the insulating film 261 formed on the carrier disk 25 may have a thickness greater than the conductive film 263. For example, the insulating film 261 may be an aluminum nitride with a thickness of 1000 Å, while the conductive film 263 may be a titanium nitride with a thickness of 300 Å.

Through the method described in this disclosure, steps 11 to 15 can be repeated and staggered stacks of the insulating film 261 and the conductive film 263 are formed on the surface of the carrier disk 25. For example, a first insulating film 2611 is formed on the surface of the carrier disk 25, and a first conductive film 2631 is formed on the surface of the first insulating film 2611, a second insulating film 2613 is formed on the surface of the first conductive film 2631, and then a second conductive film 2633 is formed on the surface of the second insulating film 2613.

In addition, if the number of times the steps 11 to 15 are repeated or the number of times the second atomic layer deposition is performed is greater than a threshold value, for example between ten and twenty times, it may be necessary to open the chamber 21, and take out the carrier disk 25 from the chamber 21 for cleaning and to remove the insulating film 261 and the conductive film 263 on the surface of the carrier disk 25.

The above mentioned is only a preferred embodiment of this disclosure and is not intended to limit the implementation scope of this disclosure, i.e. all equivalent variations and modifications of the shapes, structures, features and spirits described within the claims of this disclosure shall be included within the scope of the claims.

What is claimed is:

1. A method of using plasma enhanced process to do periodic maintenance, comprising:
performing a first atomic layer deposition on a substrate on a carrier disk to form a thin film on the substrate, wherein when the first atomic layer deposition is performed, an insulating film is formed on the carrier disk;
determining that the insulating film of the carrier disk has a thickness greater than a pre-determined value; and
performing a second atomic layer deposition on the carrier disk to form a conductive film on the insulating film of the carrier disk.

2. The method of using plasma enhanced process to do periodic maintenance according to claim 1, further comprising:
determining that the number of times the second atomic layer deposition is performed is greater than a threshold; and
cleaning the carrier disk to remove the insulating film and the conductive film on the carrier disk.

3. The method of using plasma enhanced process to do periodic maintenance according to claim 1, further comprising:
sequentially delivering a first precursor and a second precursor to a containing space of a chamber, and performing the first atomic layer deposition on the substrate on the carrier disk, wherein the carrier disk is located in the containing space of the chamber.

4. The method of using plasma enhanced process to do periodic maintenance according to claim 3, further comprising:
sequentially delivering a third precursor and the second precursor to the containing space of the chamber, and performing the second atomic layer deposition on the carrier disk in the containing space.

5. The method of using plasma enhanced process to do periodic maintenance according to claim 1, wherein the insulating film has a thickness greater than the conductive film.

6. The method of using plasma enhanced process to do periodic maintenance according to claim 1, further comprising:
taking out the substrate that has completed the first atomic layer deposition from the carrier disk, and then performing the second atomic layer deposition on the carrier disk.

7. The method of using plasma enhanced process to do periodic maintenance according to claim 6, further comprising:
after the second atomic layer deposition is completed, placing the substrate on the carrier disk, and performing the first atomic layer deposition.

8. The method of using plasma enhanced process to do periodic maintenance according to claim 1, wherein the pre-determined value is 1000 Å.

9. The method of using plasma enhanced process to do periodic maintenance according to claim 1, wherein the conductive film has a thickness greater than 300 Å.

10. The method of using plasma enhanced process to do periodic maintenance according to claim 1, wherein a precursor used for the first atomic layer deposition is different from a precursor used for the second atomic layer deposition.
